(19) United States
(12) Patent Application Publication
(10) Pub. No.: US 2017/0038208 A1
(43) Pub. Date: Feb. 9, 2017

(54) Silicon Micromachined Hemispherical Resonance Gyroscope and Processing Method Thereof

(71) Applicant: Shuwen Guo, Suzhou (CN)

(72) Inventor: Shuwen Guo, Suzhou (CN)

(73) Assignee: Suzhou Wenzhixin Micro System Technology co., Ltd., Suzhou, Jiangsu (CN)

(21) Appl. No.: 14/408,177

(22) PCT Filed: Aug. 31, 2012
(86) PCT No.: PCT/CN2012/080825

§ 371 Date: Oct. 21, 2015

(30) Foreign Application Priority Data
Jun. 15, 2012 (CN) 201210182174.5
Jul. 15, 2012 (CN) 201210231285.0

(51) Int. Cl. G01C 19/5691; H01J 37/32

(52) U.S. Cl. CPC G01C 19/5691; H01J 37/32

(57) ABSTRACT

The present invention relates to a micromachined hemispherical resonance gyroscope, which comprises a resonant layer, said resonant layer comprising a hemispherical shell which has a concave inner surface and an outer surface opposite to the inner surface, and top point of the hemispherical shell being its anchor point; several silicon hemispherical electrodes being arranged around said hemispherical shell, the silicon hemispherical electrodes including driving electrodes, equilibrium electrodes, signal detection electrodes and shielded electrodes, the shielded electrodes separating the driving electrodes and the equilibrium electrodes from the signal detection electrodes, the hemispherical shell and the several silicon spherical electrodes which surround the hemispherical shell constituting several capacitors; the resonant layer being made of polysilicon or silica or silicon oxide or diamond. The hemispherical resonance micromechanical gyroscope utilizes a processing method on the basis of silicon micromachining, which leads to small size and low production cost, as well as batch production capacity, meanwhile its sensitivity is independent of amplitude and its driving voltage could be very low, as a result its output noise could be significantly reduced, and its accuracy is better than the gyroscope products in the prior art.

### FIELD OF THE INVENTION

The present invention relates to a hemispherical resonance micromechanical gyroscope, as well as the processing method on the basis of silicon micromachining used therein.

### BACKGROUND OF THE INVENTION

A silicon micromechanical gyroscope has a wide range of application prospects in the field of inertial measurement due to its advantages such as small size, low cost, low power consumption, impact resistance and high reliability. However, accuracy of a MEMS gyroscope product is much lower than a FOG or a laser gyroscope, mainly because the accuracy depends on the size of its amplitude for most of the MEMS resonance gyroscopes, and the noise signal increases along with the increase of the amplitude, which restricts improvement of the SNR. Due to the low accuracy, its application field is greatly restricted.

A traditional hemispherical resonance gyroscope is made of quartz, and its principle is based on cup body vibration theory proposed by Professor Bryan of the university of Cambridge one hundred years ago. The theory indicates that during a hemispherical cup body rotates around the centerline of the cup, its four antinodes vibration pattern will deflect. By detecting the phase changes of the deflection vibration pattern, an angular acceleration signal could be acquired. The hemispherical resonance gyroscope has a very accurate scale factor and a satisfactory random drift and bias stability, and the gain and the scale factor of the gyroscope are independent of its material, which are only the functions of the stress wave oscillation mode on the thin shell. The gyroscope is not sensitive to the external environment (acceleration, vibration, temperature, etc.), and even the temperature compensation is not required by the gyroscope, therefore the hemispherical resonance gyroscope is recognized in the inertial technology field as one of the best gyroscope products with high performance at present, which has an accuracy higher than the FOG or the laser gyroscope, as well as additional advantages such as high resolution, wide measuring range, resistance to overload, anti-radiation, anti-interference, etc.

However, the traditional hemispherical resonance gyroscope is made of fused quartz, which makes it difficult to process and highly cost. Its price is up to several hundred thousands to a million dollars, as a result it can't be widely used. In addition, its size is also too large, and the diameter of the hemispherical resonance gyroscope with minimum size is still up to 20 mm currently. Therefore, the development of a new generation of hemispherical resonance gyroscope with miniature size and low cost naturally becomes the target in inertial technology field.

### SUMMARY OF THE INVENTION

It's an object of the present invention to provide a new type of MEMS hemispherical resonance gyroscope on the basis of phase detection principle with high accuracy, small size and low cost, as well as the processing method on the basis of silicon micromachining used therein.

The object of the present invention has been achieved by the following technical means:

A hemispherical resonance micromechanical gyroscope, which comprises a resonant layer, said resonant layer comprising a hemispherical shell and several silicon hemispherical electrodes being arranged around said hemispherical shell, said silicon spherical electrodes including driving electrodes, equilibrium electrodes, signal detection electrodes and shielded electrodes, said shielded electrodes separating said driving electrodes and said equilibrium electrodes from said signal detection electrodes, and said shielded electrodes converging at a point and the converging point being anchor point of said hemispherical shell, said hemispherical shell and said several silicon spherical electrodes which surround the hemispherical shell constituting several capacitors, and said hemispherical shell being made of polysilicon or silica or silicon oxide or diamond.

As preferred, the number of said silicon hemispherical electrodes is 20 or 24, including 8 shielded electrodes therein, and said shielded electrodes are averagely distributed along the circumferential direction of said hemispherical shell.

As preferred, the radius of said hemispherical shell is 600-1800 μm,which is typically 800-1200 μm; and the thickness of said hemispherical shell is 0.5-2.5 μm, which is typically 1.5 μm.

As preferred, the operating resonance mode of said hemispherical shell, i.e. the minimum resonance mode is four antinodes mode, and the resonant frequency is 2000-15000 Hz, which is typically 6000-8000 Hz.

As preferred, one side of said resonant layer which is close to said hemispherical shell is bonded with a first capping layer, and the other side of said resonant layer which is close to said silicon spherical hemielectrodes is bonded with a second capping layer; wherein said first capping layer is a glass plate or a silicon plate grown silica, and said second capping layer is made of glass material containing through-hole glass or silicon material containing through-hole silicon, said through-hole glass or through-hole silicon guides said silicon hemispherical electrodes to the surface of said hemispherical resonance micromechanical gyroscope.

A processing method for the hemispherical resonance micromechanical gyroscope mentioned above, which comprises following steps:
(1) isotropic etch to form a hemispherical cavity on one side of a silicon wafer;
(2) make a layer of silicon oxide grow on the inner surface of said hemispherical cavity in order to form a thermal oxide layer, then deposite a hemispherical shell layer on the outside of said thermal oxide layer, wherein said hemispherical shell layer is a polysilicon layer or a silica layer or a silicon nitride layer or a diamond film;
(3) remove said thermal oxide layer and said hemispherical shell layer outside the inner surface of said hemispherical cavity;
(4) corrode (etched by deep reactive ion etching ‘DRIE’) said silicon hemispherical electrodes arranged around said hemispherical shell layer on the other side of said silicon wafer, said thermal oxide layer being used as a barrier layer during etch, and remove said thermal oxide layer after DRIE etch, said hemispherical shell formed by the hemispherical shell layer being hunged at said anchor point, and said hemispherical shell and said several silicon spherical electrodes which surround the hemispherical shell constitute several capacitors;
(5) deposite and pattern eutectic metal on the surface of said silicon wafer to complete metallization, finally forming said resonant layer by the process.

As preferred, in the step (4), corrode deep grooves on said silicon wafer by means of lithography and DRIE etch to form said silicon hemispherical electrodes, wherein V-shaped groove lithography board is utilized during etching, and the width of said deep grooves is proportional to the thickness of said silicon wafer.

As preferred, in the step (1), said hemispherical cavity is corroded using isotropic etching method, and said isotropic etching method includes dry etching method and wet etching method.

In the step (3), said thermal oxide layer and said polysilicon layer is removed using mechanical polishing method.

In the step (4), said thermal oxide layer is corroded using gaseous hydrofluoric acid.

As preferred, the thickness of said thermal oxide layer is 1-2 μm.

As preferred, in the step (3), after said thermal oxide layer and said hemispherical shell layer are removed, bond said first capping layer to the side close to said hemispherical shell of said silicon wafer

In the step (5), bond said second capping layer to the side close to said silicon hemispherical electrodes of said silicon wafer; when said second capping layer is made of glass material, open shallow grooves on the surface of said second capping layer which is bonded to said resonant layer using anodic silicon oxide-glass bonding method, and deposite a getter film layer in said shallow grooves, then carry out the bonding; and when said second capping layer is made of silicon material, utilize silicon-silicon direct bonding method.

Due to the technical solution mentioned above, the present invention has following advantages compared with prior art:

1. The sensitivity of the silicon hemispherical resonance micromechanical gyroscope of the present invention doesn't depend on its amplitude, and it has low driving voltage, therefore its output noise could be significantly reduced, and its accuracy could be raised one to three orders of magnitude compared with the gyroscope products in the prior art;

The hemispherical resonance micromechanical gyroscope of the present invention utilizes processing method on the basis of silicon micromachining, which leads to small size and low production cost, as well as batch production capacity.

### BRIEF DESCRIPTION OF THE DRAWINGS

FIG. 1 is a distribution diagram of the silicon hemispherical electrodes of the hemispherical resonance micromechanical gyroscope of the present invention;

FIG. 2 is a diagram illustrating the shielded electrodes supporting the hemispherical shell of the hemispherical resonance micromechanical gyroscope of the present invention;

FIG. 3 is a flow chart illustrating processing method of the hemispherical resonance micromechanical gyroscope of the present invention;

FIG. 4 is a window diagram illustrating the silicon hemispherical electrodes being formed by deep grooves corrasion of the hemispherical resonance micromechanical gyroscope of the present invention;

FIG. 5 is a cross-section diagram of the silicon wafer of the hemispherical resonance micromechanical gyroscope of the present invention;

FIG. 6 is a diagram of the hemispherical resonance micromechanical gyroscope of the present invention before the second capping layer being bonded to it;

FIG. 7 is a working principle diagram of the hemispherical resonance micromechanical gyroscope of the present invention;

FIG. 8 is a four antinodes mode analysis diagram of the hemispherical resonance micromechanical gyroscope of the present invention;

FIG. 9 is a three antinodes mode analysis diagram of the hemispherical resonance micromechanical gyroscope of the present invention;

FIG. 10 is a five antinodes mode analysis diagram of the hemispherical resonance micromechanical gyroscope of the present invention;

FIG. 11 is a pendulum resonance mode analysis diagram of the hemispherical resonance micromechanical gyroscope of the present invention.

In FIGS mentioned above:
1 resonant layer; 2 hemispherical shell; 3 deep grooves; 4 driving electrodes; 5 equilibrium (or forcer) electrodes; 6 signal detection electrodes; 7 shielded electrodes; 8 thermal oxide layer; 9 first capping layer; 10 hemispherical pit

### DETAILED DESCRIPTION OF THE PREFERRED EMBODIMENTS

Now, embodiments of the present invention will be described in detail by reference to the accompanying drawings.

### The 1^{st} Embodiment

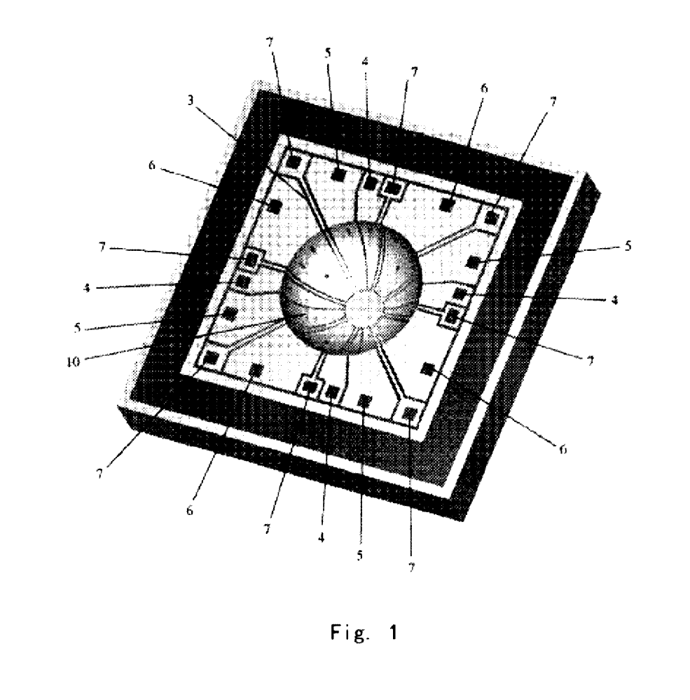

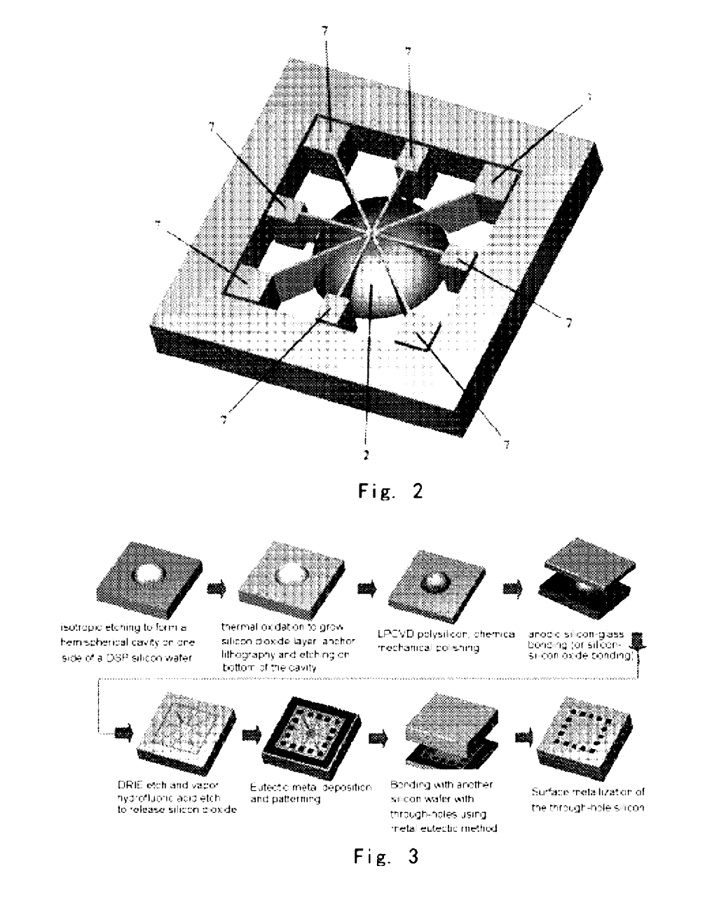

A hemispherical resonance micromechanical gyroscope, which comprises a resonant layer 1, a first capping layer 9 and a second capping layer being bonded on both sides of the resonant layer 1, as shown in FIG. 1 and FIG. 2.

The resonant layer 1 comprises a hemispherical shell 2 and several silicon spherical electrodes arranged around said hemispherical shell 2. The hemispherical shell 2 could be made of polysilicon or silica or silicon nitride or diamond, and in the present embodiment it's made of polysilicon. The silicon spherical electrodes are formed by corroding several deep grooves 3 on a silicon wafer and made of high-doped monocrystalline silicon material. The number of of said silicon spherical electrodes is 20 or 24, including driving electrodes 4, equilibrium electrodes (or forcer) 5, signal detection electrodes 6 and shielded electrodes 7. In the present embodiment, there are eight shielded electrodes 7 which are symmetrically distributed along the circumferential direction of said hemispherical shell 2, and the shielded electrodes 7 separate the driving electrodes 4 and the equilibrium electrodes 5 from the signal detection electrodes 6, therefore coupling coefficient of the driving electrodes 4 and the signal detection electrodes 6 is reduced, resulting in a reduction of quadrature error and noise. The shielded electrodes 7 converge at a point and the converging point is anchor point of the hemispherical shell 2, so that the shielded electrodes 7 could serve to support the hemispherical shell 2. The hemispherical shell 2 and several silicon spherical electrodes which surround the hemispherical shell 2 constitute several capacitors. The radius of said hemispherical shell 2 is 600-1800 μm,which is typically 800-1200 μm; and the thickness of said hemispherical shell 2 is 0.5-2.5 μm, which is typically 1.5 μm.

The first capping layer 9 is a glass plate or a silicon plate grown silica, and the second capping layer is made of glass material containing through-hole glass or silicon material containing through-hole silicon, the through-hole glass or through-hole silicon guides the silicon hemispherical electrodes to the surface of the hemispherical resonance micromechanical gyroscope.

As shown in FIG. 3, the hemispherical resonance micromechanical gyroscope mentioned above utilizes processing method on the basis of silicon micromachining. The processing method includes following steps:

(1) corrode a hemispherical cavity with a radius of 800-1200 μm on the silicon wafer(111) using isotropic etching method (including dry etching method and wet etching method), and make sure that the corroded surface is as smooth as a mirror;

(2) make a layer of thermal oxide layer 8 with thickness of about 1-2 μm grow on the inner surface of the hemispherical pit 10, then deposite a layer of LPCVD polysilicon layer on the outside of the thermal oxide layer 8, i.e. the hemispherical shell layer;

(3) remove the thermal oxide layer 8 and the polysilicon layer outside the inner surface of the hemispherical cavity 10 using mechanical polishing method, therefore the thermal oxide layer 8 and the polysilicon layer are only retained on the inner surface of the hemispherical pit 10; make silicon-glass bonding to one side of the silicon wafer close to the polysilicon layer with a glass plate using anodic oxidation method, or directly bond it with a silicon plate grown a silica layer, i.e. bond it with a first capping layer 9;

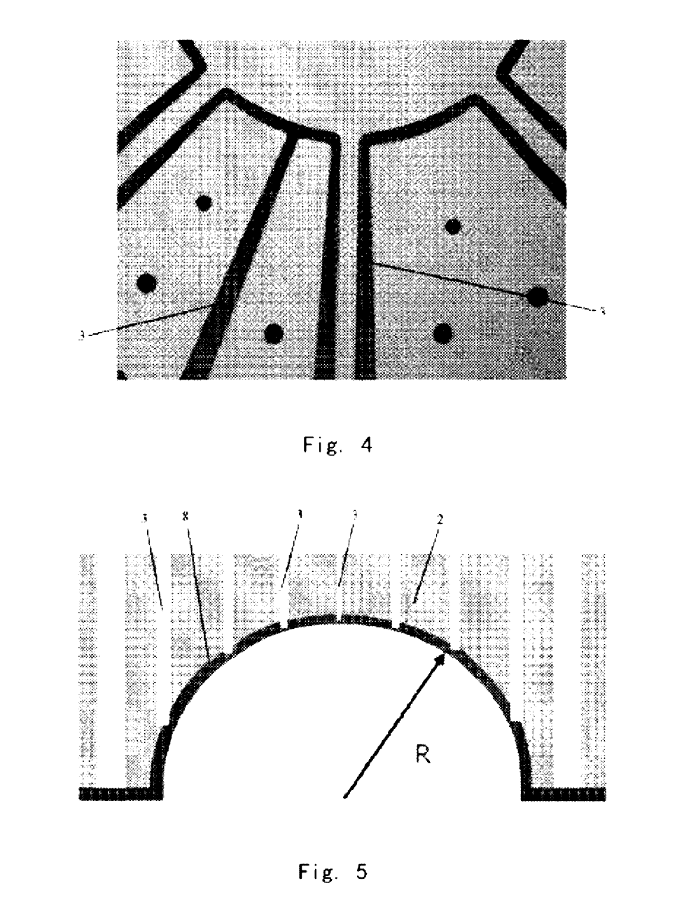

(4) etch deep grooves 3 on the other side of the silicon wafer by means of lithography and DRIE dry etch to form the silicon hemispherical electrodes surrounding the hemispherical shell 2, and sacrifice the thermal oxide layer to form the resonant layer 1. The thermal oxide layer 8 is used as a barrier layer during etch. As shown if FIG. 4 and FIG. 5, V-shaped groove lithography board is utilized during etch, and the width of said deep grooves 3 is proportional to the thickness of said silicon wafer. As the section thickness of the silicon wafer is uneven due to existence of the hemispherical pit 10, the thermal oxide layer 8 growing thereof is also spherical. During corrasion of the deep grooves 3 from top to bottom (wherein “top” and “bottom” means the top and bottom direction shown in FIG. 4), the etch rate is proportional to a window width of the deep grooves 3, and when the thinner positions of the silicon wafer has been penetrated, the etching to the thicker positions of the silicon wafer has not been finished. In order to prevent this phenomenon, the V-shaped groove lithography board mentioned above is utilized, which makes the window width of the deep grooves 3 close to the anchor point relatively narrow, and the window width of the deep grooves 3 close to the edge of the hemispherical shell 2 relatively wide. Therefore, the deep grooves 3 appearing on the silicon wafer are V-shape in the direction from the anchor point to the edge of the hemispherical shell 2. During etcing, the etch rate of the positions close to the anchor point is relatively low, and the etch rate of the positions close to the edge of the hemispherical shell 2 is relatively high, which makes sure that time of etching to the barrier layer is nearly identical in order to avoid the phenomenon that some regions have been penetrated before the etching being finished. After etching of the silicon spherical electrodes, release the thermal oxide layer 8 using gaseous hydrofluoric acid (VAPOR HF), so that the hemispherical shell layer forms the hemispherical shell 2 being hunged at the anchor point, and the hemispherical shell 2 and the several silicon hemispherical electrodes which surround the hemispherical shell form several capacitors. Traditional quartz hemispherical gyroscope utilizes the metal coating method, which leads to small transverse cross section and low signal coupling coefficient between electrodes. the electrodes of the hemispherical resonance micromechanical gyroscope of the present invention utilize high-doped monocrystalline spherical electrodes with large transverse cross section and high coupling coefficient between electrodes, which easily cause noise interference. By adding the shielded electrodes 7, it could serve to support the hemispherical shell 2 and minimize the noise interference.

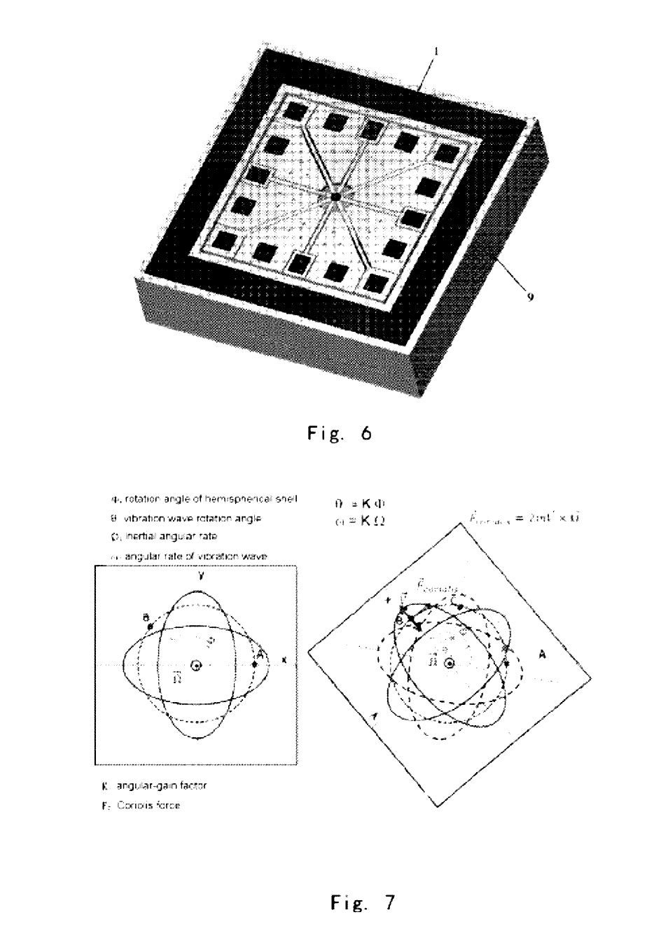

(5) deposite metal on the surface of the silicon wafer which is released after the sacrifice of the thermal oxide layer and make lithography to complete metallization, finally forming the resonant layer 1 by the process, as shown in FIG. 6. A second capping layer is vacuum bonded on the side of the resonant layer 1 close to the silicon spherical electrodes, so that the hemispherical shell 2 is absolutely closed in vacuum. The second capping layer is made of glass material containing through-hole glass or silicon material containing through-hole silicon, the through-hole glass or through-hole silicon guides the silicon spherical electrodes to the surface of the gyroscope. If the second capping layer is made of glass material, the anodic silicon oxide-glass bonding method is utilized. In order to enhance the Q value as much as possible, open shallow grooves on the surface of the second capping layer which is bonded to the resonant layer 1, and deposite a getter film layer in the shallow grooves, then carry out the bonding. If the second capping layer is made of silicon material, utilize silicon-silicon direct bonding method, which doesn't require deposite a getter film layer because it's a high-temperature bonding with high air tightness. Make lithography drilling on the second capping layer after bonding, then sputtering deposite metal electrodes and slice to finish the processing.

As shown in FIG. 7-FIG. 11, the operating principle of the present invention is as follows: when the hemispherical shell 2 rotates around the central axis as a harmonic oscillator, the coriolis effect is generated so that its vibration wave precesses relative to the hemispherical shell 2 in the ring direction. When the hemispherical shell 2 turns a angle φ around its central axis, the vibration wave turns an angle θ reversely to the hemispherical shell 2, and θ=K_{φ}, wherein K is called angular-gain factor. As long as the angle θwhich the vibration wave turns relative to the hemispherical shell 2 has been measured, the angle φ which the hemispherical shell 2 turns around the central axis could be measured, then an angular rate Ω could be obtained by differentiating the rotation angle φ, Ω=dφ/dt. So the measure object of the hemispherical resonance gyroscope is actually the phase of the resonant mode, which is different from the silicon micromechanical resonance gyroscope measuring the amplitude as usual. At present most MEMS gyroscope is on the basis of resonance amplitude measurement, and its sensitivity depends on the amplitude. However, the noise signal increases along with the increase of the amplitude, which restricts improvement of the SNR. The sensitivity of the hemispherical resonance gyroscope is independent of amplitude, and its driving voltage could be very low, as a result its output noise could be significantly reduced. Therefore the accuracy of the silicon MEMS hemispherical resonance gyroscope could be raised one to three orders of magnitude compared with the MEMS comb gyroscope products in the prior art.

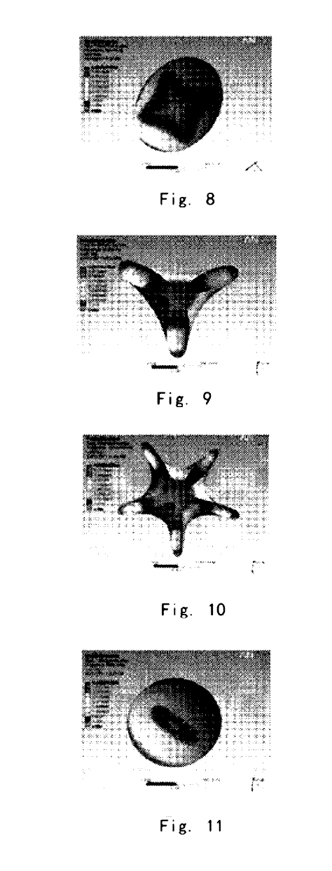

The resonance mode of the hemispherical shell 2 could be acquired by finite element analysis. Typical resonance modes has been shown in FIG. 8-FIG. 11, including four antinodes resonance mode, three antinodes resonance mode, five antinodes resonance mode and pendulum resonance mode. The operating resonance mode of the hemispherical shell 2 mentioned above, i.e. the lowest resonance mode is the four antinodes mode, the resonance frequency is 2000-15000 Hz, typically 6000-8000 Hz. The operating stability of a low resonance mode is usually better than a high order resonance mode.

The silicon hemispherical resonance gyroscope of the present invention is made using isotropic etching process, as well as 3D spherical lithography and bulk silicon production process. The diameter of the hemispherical shell 2 is about 2 mm or less, and the thickness of the hemispherical shell 2 is about 1-2 μm. Because the silicon hemispherical resonance gyroscope of the present invention utilizes MEMS micromachining method, wafer-level packaging could be achieved, as well as batch production capacity, and the cost could be significantly reduced, meanwhile advantages of the hemispherical gyroscope such as high accuracy could be retained. It's possible that the present invention could bring a revolution to the inertial technology field, and make the navigation system become universal and low price in the future.

The object of the embodiments mentioned above is only to illustrate technical ideas and characteristics of the present invention, therefore those skilled in the art could understand contents of the present invention and implement the invention, but not to limit the scope of the present invention. All the equivalent alternations or modifications according to the spirit substance of the present invention should be covered by the scope of the present invention.

1. A hemispherical resonance micromechanical gyroscope, comprising a resonant layer,
said resonant layer comprising
a hemispherical shell being made of polysilicon or silica or silicon oxide or diamond; and
several silicon spherical electrodes being arranged around said hemispherical shell, said silicon spherical electrodes including driving electrodes, equilibrium electrodes, signal detection electrodes and shielded electrodes, said shielded electrodes separating said driving electrodes and said equilibrium electrodes from said signal detection electrodes, and said shielded electrodes converging at a point and the converging point being anchor point of said hemispherical shell, said hemispherical shell and said several silicon spherical electrodes which surround the hemispherical shell constituting several capacitors,
wherein the silicon hemispherical electrodes is formed by etching deep grooves on the silicon wafer by means of lithography and DRIE dry etch with V-shaped groove lithography board being utilized during etch to make the width of said deep grooves be proportional to the thickness of said silicon wafer, i.e. the window width of the deep grooves close to the anchor point is relatively narrow, and the window width of the deep grooves close to the edge of the hemispherical shell is relatively wide.

2. A hemispherical resonance micromechanical gyroscope as set forth in claim 1, wherein the number of said silicon spherical electrodes is 20 or 24, including 8 shielded electrodes therein, and said shielded electrodes are averagely distributed along the circumferential direction of said hemispherical shell.

3. A hemispherical resonance micromechanical gyroscope as set forth in claim 1, wherein the radius of said hemispherical shell is 600-1800 μm,which is typically 800-1200 μm.

4. A hemispherical resonance micromechanical gyroscope as set forth in claim 1, wherein the thickness of said hemispherical shell is 0.5-2.5 μm, which is typically 1.5 μm.

5. A hemispherical resonance micromechanical gyroscope as set forth in claim 1, wherein the operating resonance mode of said hemispherical shell, i.e. the minimum resonance mode is four antinodes mode, and the resonant frequency is 2000-15000 Hz, which is typically 6000-8000 Hz.

6. A hemispherical resonance micromechanical gyroscope as set forth in claim 1, wherein one side of said resonant layer which is close to said hemispherical shell is bonded with a first capping layer, and the other side of said resonant layer which is close to said silicon spherical electrodes is bonded with a second capping layer; wherein said first capping layer is a glass plate or a silicon plate grown silica, and said second capping layer is made of glass material containing through-hole glass or silicon material containing through-hole silicon, said through-hole glass or through-hole silicon guides said silicon spherical electrodes to the surface of said hemispherical resonance micromechanical gyroscope.

7. A processing method for a hemispherical resonance micromechanical gyroscope as set forth in claim 1, which comprises following steps:
(1) isotropic etching a hemispherical cavity on one side of a silicon wafer;
(2) thermal oxidation to grow silicon dioxide layer on the inner surface of said hemispherical pit in order to form a thermal oxide layer, then deposit a hemispherical shell layer on the outside of said thermal oxide layer, wherein said hemispherical shell layer is a polysilicon layer or a silica layer or a silicon oxide layer or a diamond film;
(3) remove said thermal oxide layer and said hemispherical shell layer outside the inner surface of said hemispherical pit;
(4) corrode deep grooves on the silicon wafer by means of lithography and DRIE dry etch on the other side of said silicon wafer to form said silicon spherical electrodes arranged around said hemispherical shell by utilizing V-shaped groove lithography board during etch to make the width of said deep grooves be proportional to the thickness of said silicon wafer, said thermal oxide layer being used as a barrier layer during etching, and corrode said thermal oxide layer after etching, said hemispherical shell formed by the hemispherical shell layer being hunged at said anchor point, and said hemispherical shell and said several silicon spherical electrodes which surround the hemispherical shell constitute several capacitors;
(5) deposit metal on the surface of said silicon wafer and make lithography in order to complete metallization, finally forming said resonant layer by the process.

8. (canceled)

9. A processing method for a hemispherical resonance micromechanical gyroscope as set forth in claim 7, wherein said hemispherical pit is corroded using isotropic etching method, and said isotropic etching method includes dry etching method and wet etching method.

10. A processing method for a hemispherical resonance micromechanical gyroscope as set forth in claim 7, wherein in the step (3), said thermal oxide layer and said polysilicon layer is removed using mechanical polishing method.

11. A processing method for a hemispherical resonance micromechanical gyroscope as set forth in claim 7, in the step (4), said thermal oxide layer is corroded using gaseous hydrofluoric acid.

12. A processing method for a hemispherical resonance micromechanical gyroscope as set forth in claim 7, wherein the thickness of said thermal oxide layer is 1-2 μm.

13. A processing method for a hemispherical resonance micromechanical gyroscope as set forth in claim 7, wherein after said thermal oxide layer and said hemispherical shell layer outside the inner surface of said hemispherical pit are removed in the step (3), bond said first capping layer to the side close to said hemispherical shell of said silicon wafer.

14. A processing method for a hemispherical resonance micromechanical gyroscope as set forth in claim 7, further comprises bonding said second capping layer to the side close to said silicon spherical electrodes of said silicon wafer in such a way that when said second capping layer is made of glass material, open shallow grooves on the surface of said second capping layer which is bonded to said resonant layer using anodic silicon oxide-glass bonding method, and deposit a getter film layer in said shallow grooves, then carry out the bonding; and when said second capping layer is made of silicon material, utilize silicon-silicon direct bonding method.
